(19) United States
(12) Patent Application Publication
(10) Pub. No.: US 2026/0011606 A1
(43) Pub. Date: Jan. 8, 2026

(54) SEMICONDUCTOR DEVICE INCLUDING VIA STRUCTURES

(71) Applicant: Samsung Electronics Co., Ltd., Suwon-si (KR)

(72) Inventors: Minyoung KWON, Gwangmyeong-si (KR); Kwangwuk PARK, Seoul (KR); Inyoung LEE, Yongin-si (KR); Youngmin LEE, Hwaseong-si (KR); Sungdong CHO, Hwaseong-si (KR)

(73) Assignee: Samsung Electronics Co., Ltd., Suwon-si (KR)

(21) Appl. No.: 19/323,032

(22) Filed: Sep. 9, 2025

Related U.S. Application Data
(62) Division of application No. 17/879,049, filed on Aug. 2, 2022.

(30) Foreign Application Priority Data
Dec. 8, 2021 (KR) 10-2021-0175208

(51) Int. Cl. H01L 21/768; H01L 23/48; H01L 23/528

(52) U.S. Cl. CPC H01L 21/76898; H01L 21/76816; H01L 21/76897; H01L 23/481; H01L 23/5283

(57) ABSTRACT

A semiconductor device including a semiconductor substrate, an interlayer insulation layer on the semiconductor substrate, a first via structure passing through the semiconductor substrate and the interlayer insulation layer and having a first diameter, and a second via structure passing through the semiconductor substrate and the interlayer insulation layer, the second via structure having a second diameter greater than the first diameter, at a same vertical level may be provided. A sidewall of the first via structure may include at least one undercut region horizontally protruding toward a center of the first via structure, and an outer sidewall of the second via structure may be in contact with either the semiconductor substrate or the interlayer insulation layer at an area above the undercut region.

### CROSS-REFERENCE TO RELATED APPLICATION

This application is a division application based on U.S. application Ser. No. 17/879,049, filed on Aug. 2, 2022, which is based on and claims priority under 35 U.S.C. § 119 to Korean Patent Application No. 10-2021-0175208, filed on Dec. 8, 2021, in the Korean Intellectual Property Office, the disclosure of each of which is incorporated by reference herein in its entirety.

### BACKGROUND

The inventive concepts relate to semiconductor devices, semiconductor packages, and/or methods of manufacturing the semiconductor device, and more particularly, to semiconductor devices which quickly process data and have low power consumption, semiconductor packages, and/or a methods of manufacturing the semiconductor device.

As 3-dimensional (3D) packages where a plurality of semiconductor chips are stacked in one semiconductor package are actively developed, through-silicon-via (TSV) technology where an electrical connection is vertically formed via a substrate or a die is being very significantly recognized. In order to enhance the performance of 3D packages, a data speed and power consumption have to be improved.

### SUMMARY

The inventive concepts provide semiconductor devices which quickly process data and have low power consumption.

The inventive concepts provide semiconductor packages which quickly process data and have low power consumption.

According to an aspect of the inventive concepts, a semiconductor device includes a semiconductor substrate, an interlayer insulation layer on the semiconductor substrate, a first via structure passing through the semiconductor substrate and the interlayer insulation layer, the first via structure having a first diameter, and a second via structure passing through the semiconductor substrate and the interlayer insulation layer, the second via structure having a second diameter, is the second diameter being greater than the first diameter, at a same vertical level. A sidewall of the first via structure includes at least one undercut region horizontally protruding toward a center of the first via structure, and an outer sidewall of the second via structure is in contact with either the semiconductor substrate or the interlayer insulation layer an area above the undercut region.

According to another aspect of the inventive concepts, a semiconductor device includes a semiconductor substrate, an interlayer insulation layer on the semiconductor substrate, a signal via structure passing through the semiconductor substrate and the interlayer insulation layer, and a power via structure passing through the semiconductor substrate and the interlayer insulation layer. A sidewall of the signal via structure includes at least one undercut region horizontally protruding toward a horizontal center of the signal via structure, a height of the signal via structure is same as a height of the power via structure, the signal via structure has a first diameter and the power via structure has a second diameter, the second diameter being greater than the first diameter at a same vertical level, and an outer sidewall of the power via structure is in contact with the semiconductor substrate or the interlayer insulation layer at an area above the undercut region.

According to another aspect of the inventive concepts, a semiconductor package includes a first semiconductor device including a cell region and a peripheral region and a second semiconductor device stacked on the first semiconductor device and electrically connected to the first semiconductor device. The first semiconductor device includes a semiconductor substrate and an interlayer insulation layer on the semiconductor substrate, the first semiconductor device further includes a first via structure and a second via structure disposed in the peripheral region, the first via structure passing through the semiconductor substrate and the interlayer insulation layer and having a first diameter in the peripheral region, and the second via structure passing through the semiconductor substrate and the interlayer insulation layer and having a second diameter which is greater than the first diameter, a sidewall of the first via structure includes at least one undercut region horizontally protruding toward a center of the first via structure, and a height of the first via structure is same as a height of the second via structure, and an outer sidewall of the second via structure is in contact with either the semiconductor substrate or the interlayer insulation layer at an area above the undercut region.

According to another aspect of the inventive concepts, a method of manufacturing a semiconductor device includes forming an interlayer insulation layer on a semiconductor substrate, forming a mask material layer on the interlayer insulation layer, removing a portion of the mask material layer on an upper surface of the mask material layer at each of a first position for forming a first via structure having a first diameter and a second position for forming a second via structure having a second diameter, removing both the interlayer insulation layer and a portion of the semiconductor substrate at the first position to form a first preliminary recess, removing at least a portion of the interlayer insulation layer at the second position to form a second preliminary recess, simultaneously etching portions of the semiconductor substrate at positions of the first and second preliminary recesses to form a first via hole and a second via hole, forming the first via structure and the second via structure in the first via hole and the second via hole, respectively, and forming external connection terminals electrically connected to the first via structure and the second via structure, wherein a depth of the first preliminary recess is greater than a depth of the second preliminary recess, a diameter of the first preliminary recess is smaller than a diameter of the second preliminary recess, and the removing the portion of the mask material layer at the second position includes performing exposure on the mask material layer by using a reticle including a scattering bar, the scattering bar being disposed on the upper surface of the mask material layer at the second position.

### BRIEF DESCRIPTION OF THE DRAWINGS

Some example embodiments of the inventive concepts will be more clearly understood from the following detailed description taken in conjunction with the accompanying drawings in which:

FIG. 1 is a plan arrangement view for describing a semiconductor device according to an example embodiment;

FIG. 2 is an enlarged view illustrating a first through-silicon-via (TSV) unit region of FIG. 1;

FIG. 3 is a side view illustrating a cross-sectional surface taken along line III-III′ of FIG. 2 in a semiconductor device according to an example embodiment;

FIGS. 4A and 4B are partial enlarged views illustrating in detail a region illustrated by IV of FIG. 3;

FIG. 5 is a side view illustrating a cross-sectional surface taken along line III-III′ of FIG. 2 in a semiconductor device according to an example embodiment;

FIG. 6 is a side view illustrating a cross-sectional surface of a semiconductor device according to an example embodiment;

FIG. 7 is a flowchart illustrating a method of manufacturing a semiconductor device, according to an example embodiment; FIGS. 8A to 8I are side cross-sectional views illustrating a method of manufacturing the semiconductor device;

FIG. 9 is a flowchart illustrating in more detail an operation of forming first and second preliminary recesses;

FIG. 10 is a flowchart illustrating in more detail an operation of forming a first via structure via hole and a second via structure via hole;

FIGS. 11A to 11D are side cross-sectional views illustrating a method of manufacturing a semiconductor device, according to an example embodiment; and

FIG. 12 is a cross-sectional view illustrating a main configuration of a semiconductor package according to an example embodiment.

### DETAILED DESCRIPTION

Hereinafter, some example embodiments will be described in detail with reference to the accompanying drawings. Like reference numerals refer to like elements, and their repeated descriptions are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

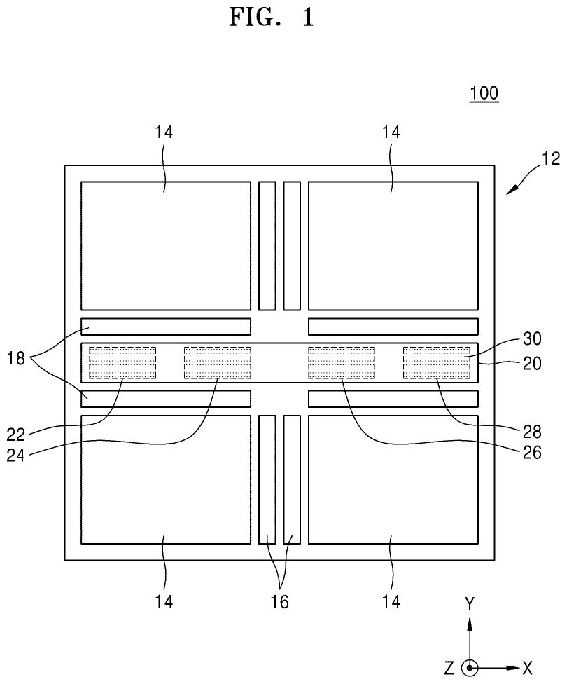

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. FIG. 1 is a plan arrangement view for describing a semiconductor device 100 according to an example embodiment.

Referring to FIG. 1, the semiconductor device 100 may include a plurality of cell regions 14. A plurality of memory cells may be arranged in the plurality of cell regions 14. A plurality of word lines, a plurality of bit lines, and a sense amplifier may be arranged in the plurality of cell regions 14 on the basis of various schemes. A peripheral region may be provided near the plurality of cell regions 14, and the peripheral region may include a plurality of column decoders 16, a plurality of row decoders 18, and a through-silicon-via (TSV) region 20. The plurality of column decoders 16 may receive and decode an address to select a column line of the cell region 14. The plurality of row decoders 18 may receive and decode an address to output a row address for selecting a row line of the cell region 14. A memory semiconductor chip 12 may include a write driver, an input/output (I/O) sense amplifier, and an I/O buffer.

The TSV region 20 may be disposed at an approximate center portion of the memory semiconductor chip 12. A plurality of TSV structures 30 may be arranged in the TSV region 20. The number and shape of TSV structures 30 illustrated in FIG. 1 may be merely an example embodiment, and the inventive concepts are not limited to the illustration of FIG. 1. For example, about hundreds or thousands of TSV structures 30 may be arranged in the TSV region 20.

The I/O buffer included in the memory semiconductor chip 12 may receive a signal from the outside through the TSV structure 30, or may transmit a signal to the outside through the TSV structure 30.

The TSV region 20 may include a plurality of first to fourth TSV unit regions 22, 24, 26, and 28. The plurality of first to fourth TSV unit regions 22, 24, 26, and 28 may include a first TSV unit region 22, a second TSV unit region 24, a third TSV unit region 26, and a fourth TSV unit region 28. In FIG. 1, the TSV region 20 is illustrated as including four TSV regions (e.g., first to fourth TSV unit regions 22, 24, 26, and 28), but the inventive concepts are not limited to the illustration of FIG. 1. The TSV region 20 may include a different number of TSV unit regions.

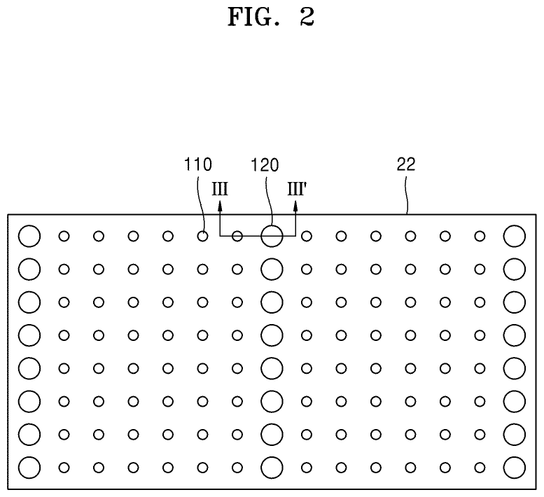

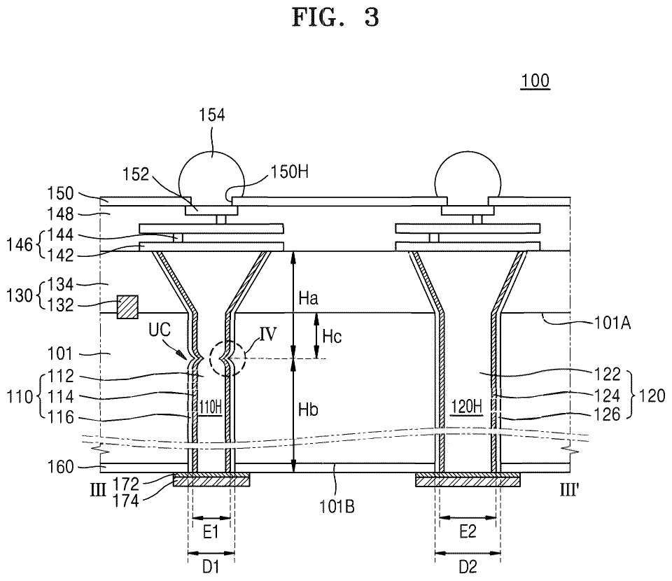

FIG. 2 is an enlarged view illustrating the first TSV unit region 22 of FIG. 1. In FIG. 2, the first TSV unit region 22 is illustrated, but it may be understood that the second TSV unit region 24, the third TSV unit region 26, and the fourth TSV unit region 28 are identically illustrated also.

Referring to FIG. 2, a plurality of via structures 110 and 220 may be disposed in the first TSV unit region 22. The via structures 110 and 120 may include a first via structure 110 having a relatively smaller diameter and a second via structure 120 having a relatively larger diameter. For example, the first via structure 110 may include a signal via structure, and the second via structure 120 may include a power via structure.

The second via structure 120 may have a relatively lower resistance because of having a relatively larger diameter and may be a power transfer path for more efficiently supplying power. The first via structure 110 may have a relatively lower capacitance because of having a relatively smaller diameter and may be a signal transfer path for providing a high data transfer speed.

In some example embodiments, a plurality of first via structures 110 each corresponding to a signal transfer path may be arranged in a lattice form, and a plurality of second via structures 120 each corresponding to a power transfer path may be arranged in a 1-shaped form (e.g., a line form). However, the inventive concepts are not limited to such arrangement.

FIG. 3 is a side view illustrating a cross-sectional surface taken along line III-III′ of FIG. 2 in a semiconductor device 100 according to an example embodiment.

Referring to FIG. 3, the semiconductor device 100 may include a semiconductor substrate 101, an interlayer insulation layer 134 formed on the semiconductor substrate 101, a first via structure 110 passing through the semiconductor substrate 101 and the interlayer insulation layer 134, and a second via structure 120 passing through the semiconductor substrate 101 and the interlayer insulation layer 134.

The semiconductor substrate 101 may include a semiconductor such as silicon (Si) or germanium (Ge) or a compound semiconductor such as silicon carbide (SiC), gallium arsenide (GaAs), indium arsenide (InAs), or indium phosphide (InP). In at least one example embodiment, the semiconductor substrate 101 may have a silicon on insulator (SOI) structure. For example, the semiconductor substrate 101 may include a buried oxide (BOX) layer. In some example embodiments, the semiconductor substrate 101 may include a conductive region (e.g., an impurity-doped well) or an impurity-doped structure. Also, the semiconductor substrate 101 may include various isolation layers (not shown) such as a shallow trench isolation (STI) structure.

The interlayer insulation layer 134 may be configured as a single material layer, or may be configured as a multi material layer where two or more material layers are stacked. In some example embodiments, the interlayer insulation layer 134 may include a tetraethylorthosilicate (TEOS) film, a high density plasma (HDP) film, a boro-phospho-silicate glass (BPSG) film, a flowable chemical vapor deposition (FCVD) oxide film, or an ultra low K (ULK) film having an ultra low dielectric constant K of about 2.2 to about 2.4. The ULK film may include may include, for example, a SiOC layer or a SiCOH layer. In some example embodiments, the interlayer insulation layer 134 may include a layer including silicon nitride (SiN) or silicon oxynitride (SiON).

Various kinds of a plurality of semiconductor devices 132 may be provided in the interlayer insulation layer 134 and the semiconductor substrate 101. The semiconductor device 132 may include microelectronic devices, and for example, may a metal-oxide-semiconductor field effect transistor (MOSFET) image sensor, system large scale integration (LSI), or a complementary metal oxide semiconductor (CMOS) imaging sensor (CIS), a micro-electro-mechanical system (MEMS), an active element, and/or a passive element. The semiconductor device 132 may be electrically connected to the conductive region of the semiconductor substrate 101. The semiconductor device 132 and the interlayer insulation layer 134, formed before forming a multi wiring structure, may be referred to as a front-end-of-line (FEOL) structure 130. According to other example embodiments, the semiconductor device 132 may be electrically disconnected from other semiconductor devices 132 adjacent thereto by an isolation layer.

The isolation layer may be configured as a single material layer, or may be configured as a multi material layer where two or more material layers are stacked. In some example embodiments, the isolation layer may have an STI structure. In some example embodiments, an upper surface of the isolation layer may be disposed on substantially the same plane as an upper surface 101A of the semiconductor substrate 101. In some example embodiments, the isolation layer may include silicon oxide, silicon nitride, silicon oxynitride, or a combination thereof.

A first via hole 110H may be formed to pass through the semiconductor substrate 101 and the interlayer insulation layer 134. The first via structure 110 may include a first via insulation layer 116 which covers a sidewall of the first via hole 110H, a first barrier layer 114 which covers a sidewall of the first via insulation layer 116, and a first via plug 112 which fills an inner space defined by the first barrier layer 114.

In some example embodiments, the first via insulation layer 116 may conformally cover the sidewall of the first via hole 110H. For example, the first via insulation layer 116 may extend to have a substantially uniform thickness along the sidewall of the first via hole 110H. The first via insulation layer 116 may include oxide, nitride, carbide, a polymer, or a combination thereof. In some example embodiments, the first via insulation layer 116 may be formed by a chemical vapor deposition (CVD) process. In some example embodiments, the first via insulation layer 116 may have a thickness of about 500 Å to about 2,500 Å.

Also, the sidewall of the first via hole 110H may include at least one undercut region UC. The undercut region UC may denote a portion of the sidewall of the first via hole 110H which horizontally protrudes toward a center of the first via hole 110H. The first via hole 110H, as described below, may be formed by a process such as a deep reactive ion etching process, and in this case, a fine concave-convex portion may be formed in the sidewall of the first via hole 110H and the undercut region UC may considerably protrude compared to the fine concave-convex portion.

Also, according to an example embodiment, a range of a height of each of the first and second via structures 110 and 120 may be about 30 μm to about 150 μm. According to an example embodiment, a distance Ha from the undercut region UC to an upper surface of the first via structure 110 may be less than a distance Hb from the undercut region UC to a lower surface of the first via structure 110. For example, a range of the distance Hb from the undercut region UC to the lower surface of the first via structure 110 may be about 200% to about 500% of the distance Ha from the undercut region UC to the upper surface of the first via structure 110. Also, a range of a distance Hc from a lower surface of the interlayer insulation layer 134 to the undercut region UC may be about 5 μm to about 15 μm.

In FIG. 3, the first via hole 110H is illustrated as including one undercut region UC, but the inventive concepts are not limited thereto. The first via hole 110H may also include more undercut regions UC than one (for example, two or more undercut regions UC).

In some example embodiments, the first barrier layer 114 may extend to have a substantially uniform thickness along the sidewall of the first via insulation layer 116. The first barrier layer 114 may include a conductive layer having a relatively low wiring resistance. For example, the first barrier layer 114 may include a single layer or a multilayer including at least one material selected from among tungsten (W), tungsten nitride (WN), tungsten carbide (WC), titanium (Ti), titanium nitride (TiN), tantalum (Ta), tantalum nitride (TaN), ruthenium (Ru), cobalt (Co), manganese (Mn), nickel (Ni), and nickel boride (NiB). For example, the first barrier layer 114 may include a multilayer including TaN/W, TiN/W, or WN/W. The first barrier layer 114 may have a thickness of about 500 Å to about 1,000 Å. In some example embodiments, the first barrier layer 114 may be formed by a physical vapor deposition (PVD) process, a CVD process, or an atomic layer deposition (ALD) process, but the inventive concepts are not limited thereto.

The second via structure 120 may include a second via insulation layer 126 which covers a sidewall of a second via hole 120H, a second barrier layer 124 which covers a sidewall of the second via insulation layer 126, and a second via plug 122 which fills an inner space defined by the second barrier layer 124.

The second via insulation layer 126, the second barrier layer 124, and the second via plug 122 may be the same as or substantially similar to the first via insulation layer 116, the first barrier layer 114, and the first via plug 112, respectively. The first via insulation layer 116, the first barrier layer 114, and the first via plug 112 have been described above, and thus, detailed descriptions of the second via insulation layer 126, the second barrier layer 124, and the second via plug 122 are omitted.

In some example embodiments, a horizontal cross-sectional surface of each of the first and second via structures 110 and 120 may have, for example, a circular shape, a polygonal shape, or an oval shape, which is planar. However, the inventive concepts are not limited thereto. A width of each of the first and second via structures 110 and 120 in a horizontal direction in the interlayer insulation layer 134 may have a constant change rate. Also, the first and second via structures 110 and 120 may have the same height. A height of the first or second via structure 110 or 120 may denote a vertical-direction (Z-direction) length.

The first via structure 110 may have a first diameter D1, and the second via structure 120 may have a second diameter D2 which is greater than the first diameter D1 at the same vertical level. Each of the first diameter D1 and the second diameter D2 may be a diameter measured on an outer diameter of a corresponding one of the first via insulation layer 116 and the second via insulation layer 126. For example, a range of the first diameter D1 may be about 2 μm to about 4 μm, and a range of the second diameter D2 may be about 3 μm to about 8 μm. In some example embodiments, the second diameter D2 may be about 1 μm to about 5 μm greater than the first diameter D1. For example, a range of a ratio of the second diameter D2 to the first diameter D1 may be about 110% to about 200%.

The first barrier layer 114 of the first via structure 110 may have a first barrier width E1 limited by an outer diameter of the first barrier layer 114, and the second barrier layer 124 of the second via structure 120 may have a second barrier width E2 limited by an outer diameter of the second barrier layer 124. In some example embodiments, the second barrier width E2 may be greater than the first barrier width E1. In some example embodiments, the second barrier width E2 may be about 1 μm to about 4 μm greater than the first barrier width E1.

One end of each of the first via structure 110 and the second via structure 120 may be electrically connected to a multilayer wiring structure 146 including a plurality of metal wiring layers 142 and a plurality of contact plugs 144. In FIG. 3, it is illustrated that the multilayer wiring structure 146 directly contacts the first and second via structures 110 and 120, but another conductor may be disposed between the multilayer wiring structure 146 and the first or second via structure 110 or 120 to electrically connect the multilayer wiring structure 146 to the first or second via structure 110 or 120. Also, a plurality of multilayer wiring structures 146 may be insulated from one another by an inter-metal-layer insulation layer 148.

In some example embodiments, an upper insulation layer 150 may be formed on the inter-metal-layer insulation layer 148. The upper insulation layer 150 may include silicon oxide, silicon nitride, a polymer, or a combination thereof. A hole 150H exposing a bonding pad 152 connected to the multilayer wiring structure 146 may be formed on the upper insulation layer 150. The bonding pad 152 may be connected to an upper connection terminal 154 through the hole 150H.

The other end of each of the first via structure 110 and the second via structure 120 may be covered by the conductive layer 172. The connection terminal 174 may be electrically connected to the first via structure 110 and the second via structure 120 through the conductive layer 172.

The upper connection terminal 154 and the connection terminal 174 are not limited to a shape illustrated in FIG. 3. Each of the upper connection terminal 154 and the connection terminal 174 may have the form of a conductive pad, a solder ball, a solder bump, or a redistribution conductive layer. In some example embodiments of the semiconductor device 100, the upper connection terminal 154 is omitted.

Furthermore, the semiconductor device 100 according to an example embodiment may not include an etch delay layer. Therefore, an outer sidewall of each of the first and second via structures 110 and 120 may be in contact with either the semiconductor substrate 101 or the interlayer insulation layer 134 at an area above the undercut region UC. For example, the outer sidewall of each of the first and second via structures 110 and 120 may be in contact with the semiconductor substrate 101 or the interlayer insulation layer 134 at a same vertical level. For example, the outer sidewall of each of the first and second via structures 110 and 120 may be only in contact with the semiconductor substrate 101 and the interlayer insulation layer 134 without being in contact with an etch delay layer. The etch delay layer may be disposed inward from the semiconductor substrate 101, inward from the interlayer insulation layer 134, or between the semiconductor substrate 101 and the interlayer insulation layer 134 and may denote a material forming an etch speed difference between the first via hole 110H and the second via hole 120H, regardless of a name thereof. That is, the etch delay layer may denote a material layer which has an etch selectivity with respect to the semiconductor substrate 101 or has an etch selectivity with respect to the interlayer insulation layer 134. For example, the etch delay layer may include at least one of a SiN-based material, an oxide-based material, a Si-based material (for example, SiGe), a metal-based material, and a carbon-based material.

General semiconductor devices include an etch delay layer inward from a semiconductor substrate or inward from an interlayer insulation layer, so as to induce a diameter difference between first and second via structures. In a case where the etch delay layer is provided, the etch delay layer may contact an outer wall of the first or second via structure after the first and second via structures are formed, and due to this, the reliability of a semiconductor device may be relatively low.

On the other hand, because the semiconductor device 100 according to an example embodiment does not include the etch delay layer, pollutants may not be included in the semiconductor substrate 101 or the interlayer insulation layer 134 in forming the first and second via structures 110 and 120. Accordingly, reliability of the semiconductor device 100 may be relatively high.

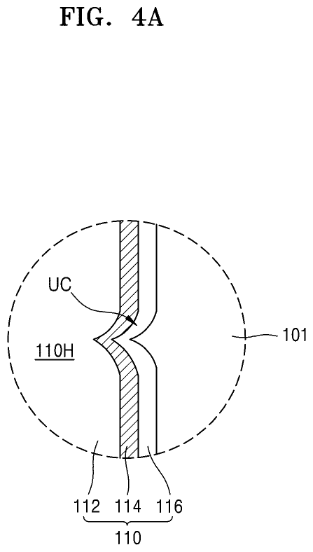

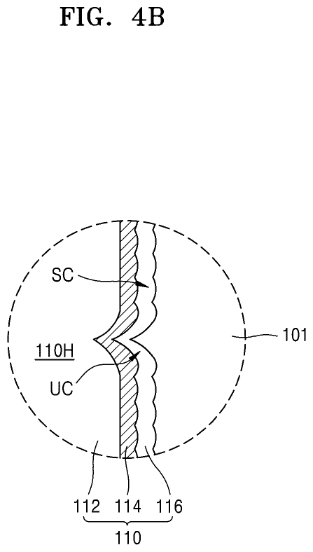

FIGS. 4A and 4B are partial enlarged views illustrating in detail a region illustrated by IV of FIG. 3.

Referring to FIG. 4A, the undercut region UC horizontally protruding toward a center of the first via hole 110H may be provided in the first via hole 110H. Based on a protrusion shape of the undercut region UC, the first via insulation layer 116 and the first barrier layer 114 sequentially stacked thereon may have a protrusion shape. Because the first via insulation layer 116 and the first barrier layer 114 are conformally formed to have a substantially constant thickness, a protrusion shape of the undercut region UC of the first via hole 110H may be identically or similarly transferred to the first via insulation layer 116 and the first barrier layer 114.

Referring to FIG. 4B, a plurality of scallops SC and a protrusion undercut region UC may be provided in the first via hole 110H. A horizontal width of each of the scallops SC may be less than that of the undercut region UC. The first via hole 110H may be formed by a Bosch process. For example, an inductive coupled plasma deep reactive ion etching (ICP DRIE) process using SF₆ or O₂ plasma and a sidewall passivation process using one of CFₓ-based materials such as C₄F₈ may be repeated a plurality of times for forming the first via hole 110H in the semiconductor substrate 101. As a result, as illustrated in FIG. 4B, the first via hole 110H including the plurality of scallops SC may be formed. According to another example embodiment, the first via hole 110H may be formed by an ALD process or a CVD process.

Based on protrusion shapes of the undercut region UC and the scallops SC, the first via insulation layer 116 and the first barrier layer 114 sequentially stacked thereon may have a shape corresponding to the protrusion shapes.

In an interface between the first via insulation layer 116 and the first barrier layer 114, a concave-convex portion of the scallops SC may be reduced compared to a sidewall of the first via hole 110H. In some example embodiments, the interface between the first via insulation layer 116 and the first barrier layer 114 may include an interface to which the concave-convex portion of the scallops SC is not transferred.

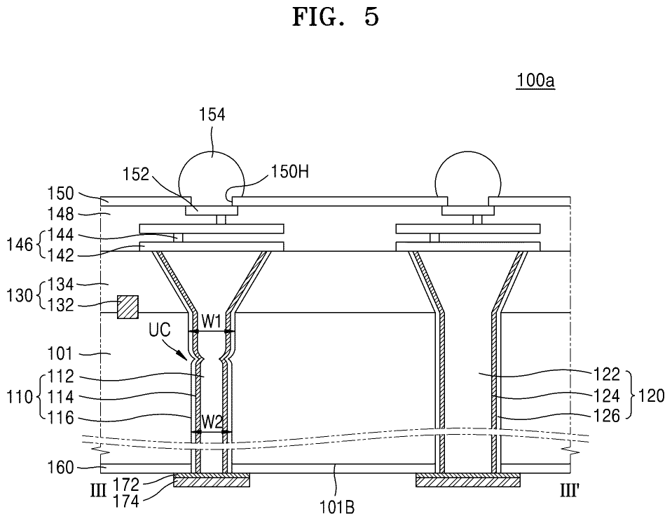

FIG. 5 is a side view illustrating a cross-sectional surface taken along line III-III′ of FIG. 2 in a semiconductor device 100a according to an example embodiment. Comparing the example embodiment of FIG. 5 with the example embodiment of FIG. 3, there may merely be a difference in that the first via structure 110 differs in an upper portion and a lower portion of the undercut region UC, and the other features may be the same. Hereinafter, therefore, such a difference will be mainly described.

Referring to FIG. 5, the first via structure 110 may have a first width W1 in an upper portion of the undercut region UC and may have a second width W2 in a lower portion of the undercut region UC. The first width W1 may differ from the second width W2. In some example embodiments, the first width W1 may be greater than the second width W2. In some example embodiments, the first width W1 may be less than the second width W2. Each of the first width W1 and the second width W2 may be less than a diameter D2 (see FIG. 3) of the second via structure 120.

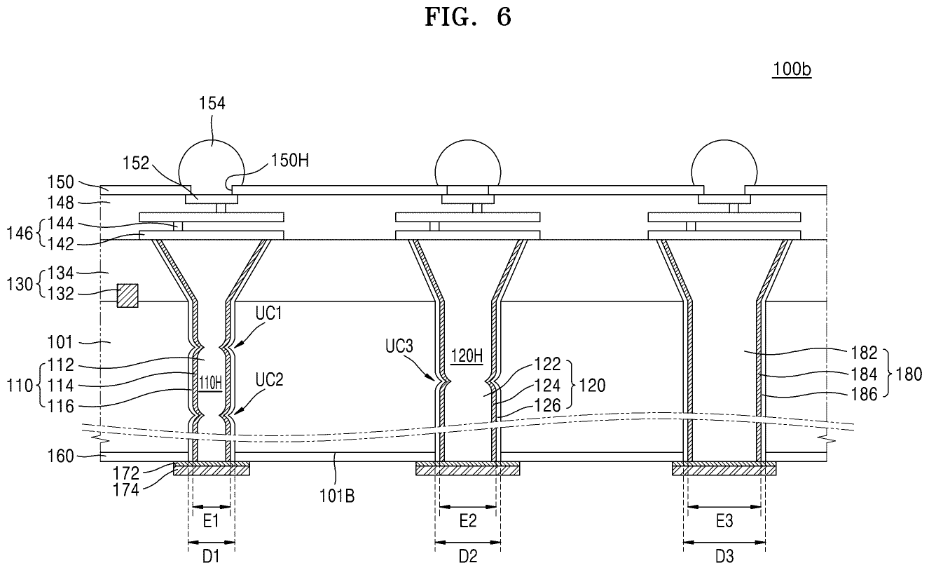

FIG. 6 is a side view illustrating a cross-sectional surface of a semiconductor device 100b according to an example embodiment. Comparing the example embodiment of FIG. 6 with the example embodiment of FIG. 3, there may merely be a difference in that the semiconductor device 100b further includes a third via structure 180 having a third diameter D3 which is greater than a second diameter D2, and the other features may be the same. Hereinafter, therefore, such a difference will be mainly described.

Referring to FIG. 6, a third via structure 180 may have a third diameter D3 and may include a third via plug 182, a third barrier layer 184 which is formed on a surface of the third via plug 182 to have a substantially uniform thickness, and a third via insulation layer 186 which is formed on a surface of the third barrier layer 184 to have a substantially uniform thickness.

Except for a dimension, the third via plug 182, the third barrier layer 184, and the third via insulation layer 186 may be the same as or substantially similar to the first via plug 112, the first barrier layer 114, and the first via insulation layer 116, and thus, their detailed descriptions are omitted.

The third via structure 180 may have the third diameter D3, and the third diameter D3 may be greater than the second diameter D2 of the second via structure 120. In some example embodiments, the third diameter D3 may be about 1 μm to about 5 μm greater than the second diameter D2. The third diameter D3 may be a diameter measured on an outer diameter of the third via insulation layer 186.

The third barrier layer 184 of the third via structure 180 may have a third barrier width E3, and the third barrier width E3 may be greater than a second barrier width E2 of the second via structure 120. The third barrier width E3 may be about 1 μm to about 4 μm greater than the second barrier width E2.

In this case, the first via structure 110 may include two or more first undercut regions UC1 and UC2. Further, the second via structure 120 may include one or more second undercut regions UC3. The second undercut region UC3 may denote a portion of a sidewall of the second via hole 120H which horizontally protrudes toward a center of the second via hole 120H. The first via structure 110 may include more undercut regions UC than the second via structure 120. In some example embodiments, the first via structure 110 may include two first undercut regions UC1 and UC2, and the second via structure 120 may include one second undercut region UC3.

In some example embodiments, a vertical level of the second undercut region UC3 of the second via structure 120 may be between a vertical level of the first undercut region UC1 of the first via structure 110 and a vertical level of the first undercut region UC2 of the first via structure 110. In other words, with respect to a lower surface 101B of the semiconductor substrate 101, a vertical level of a first lower undercut region UC2 of the first via structure 110 may be lowest, a vertical level of a first upper undercut region UC1 of the first via structure 110 may be highest, and a vertical level of the second undercut region UC3 of the second via structure 120 may be therebetween. In other example embodiments, a vertical level of each of the first undercut regions UC1 and UC2 may differ from that of the second undercut region UC3.

In other example embodiments, an isolation layer surrounding the third via structure 180 in a horizontal direction may be provided over a certain height to contact a side surface of the third via structure 180.

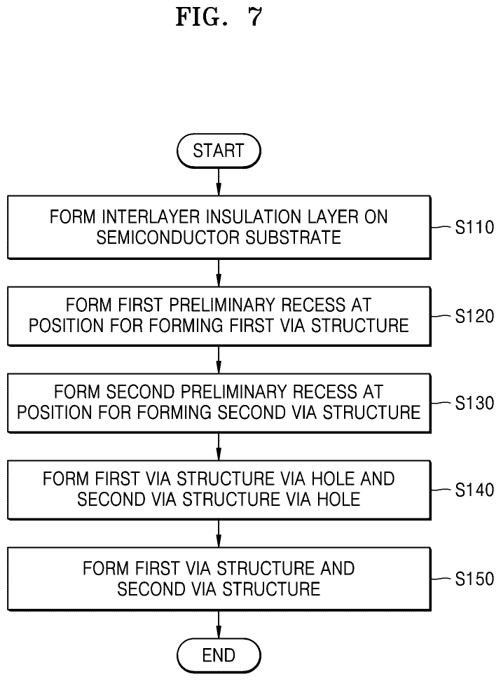

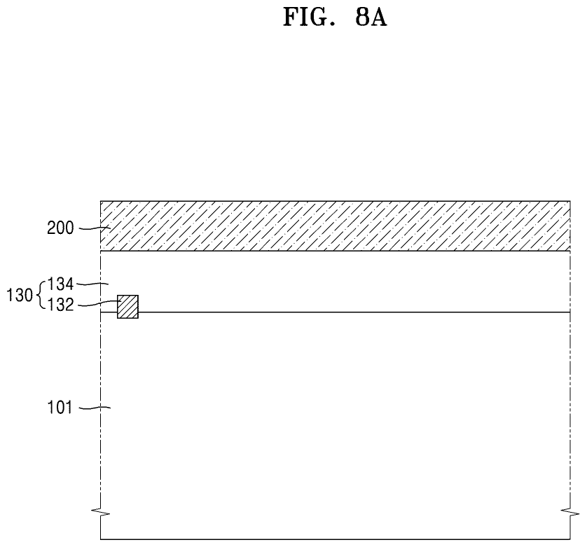

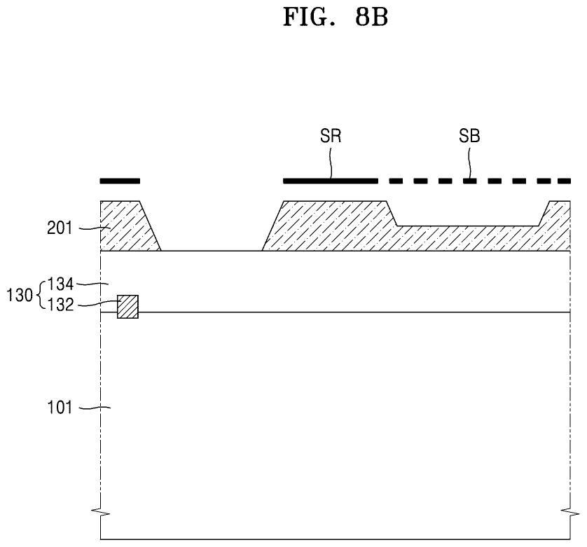

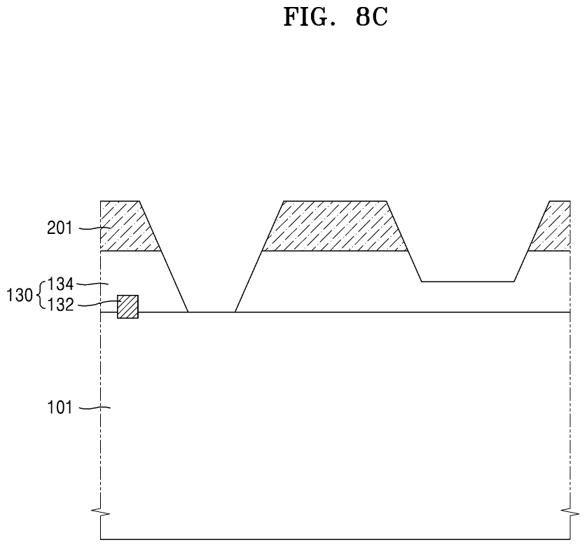

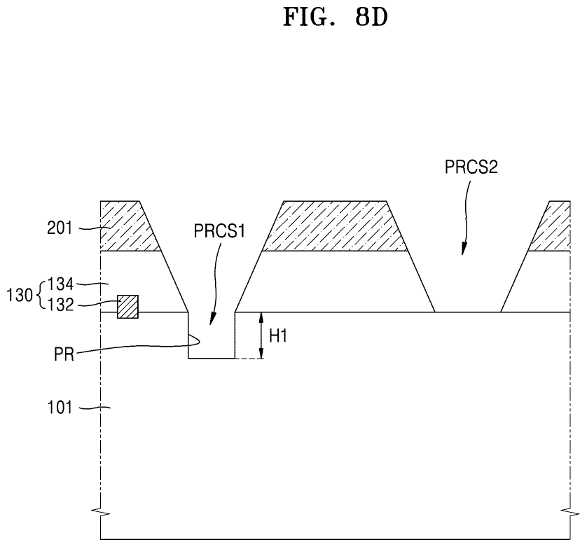

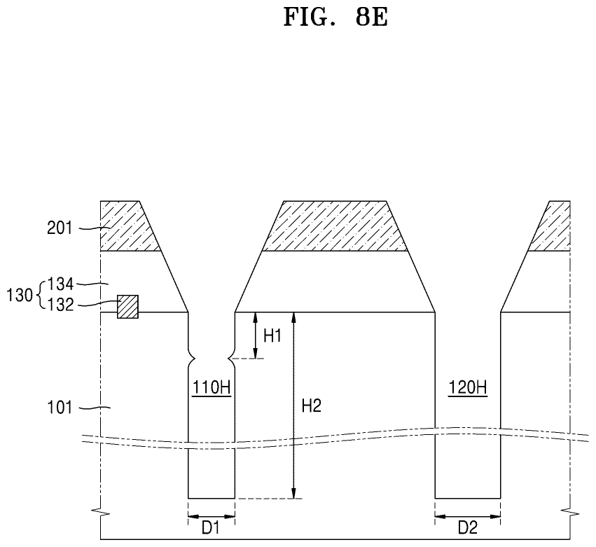

FIG. 7 is a flowchart illustrating a method of manufacturing a semiconductor device 100, according to an example embodiment. FIGS. 8A to 8I are side cross-sectional views illustrating a method of manufacturing the semiconductor device 100.

Referring to FIGS. 7 and 8A, an interlayer insulation layer 134 may be formed on a semiconductor substrate 101 in operation S110. In some example embodiments, a semiconductor device 132 may be formed on the semiconductor substrate 101 before forming the interlayer insulation layer 134. As described above, the semiconductor device 132 and the interlayer insulation layer 134 formed before forming a multilayer wiring structure may be referred to as an FEOL structure (130 of FIG. 3). Subsequently, a mask material layer 200 may be coated and formed on the interlayer insulation layer 134.

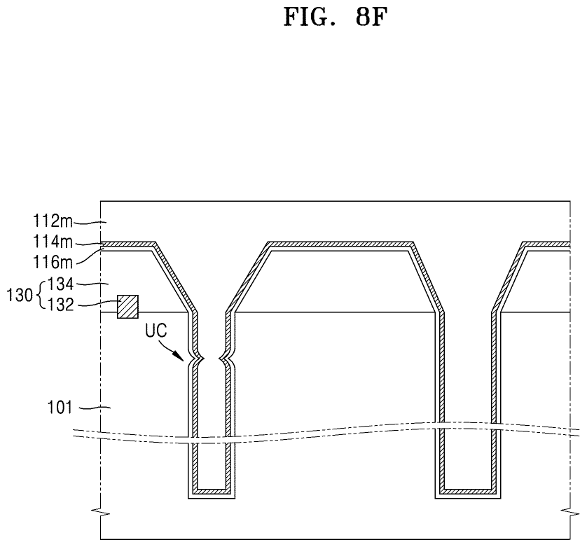

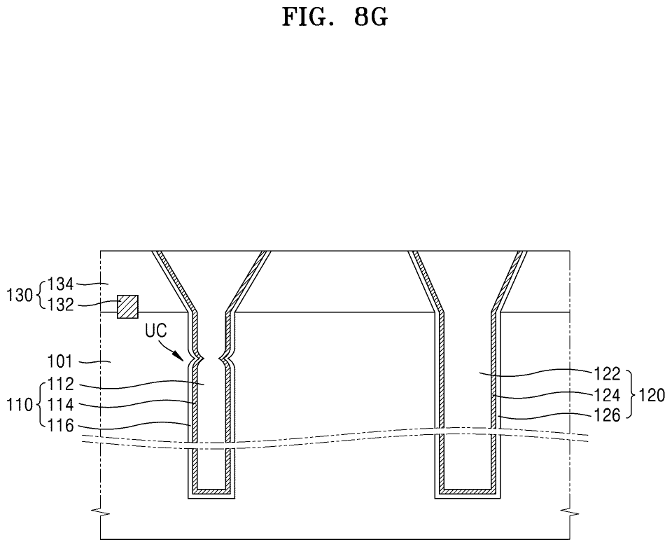

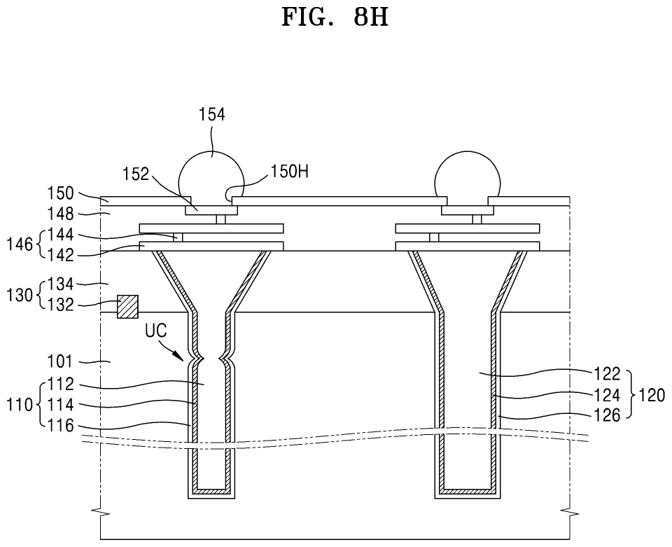

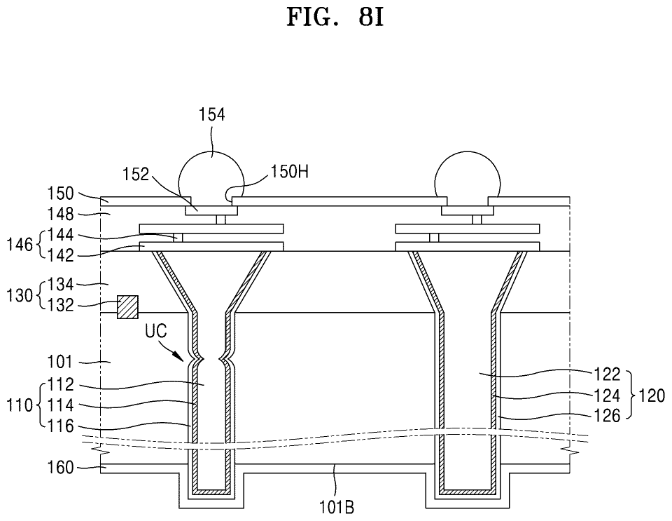

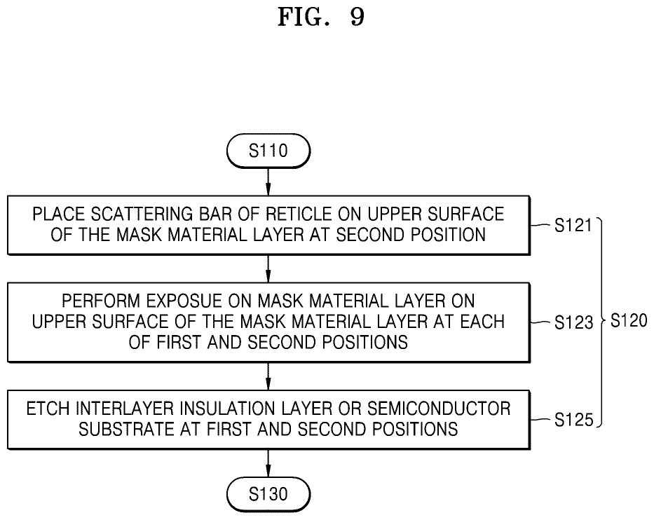

Referring to FIGS. 7, 8B, and 9, a mask material layer 200 on an upper surface of the interlayer insulation layer 134 at a position (hereinafter referred to as a first position) for forming the first via structure 110 may be etched, and a portion of the mask material layer 200 on an upper surface of the interlayer insulation layer 134 at a position (hereinafter referred to as a second position) for forming the second via structure 120 may be removed. As a portion of the mask material layer 200 is removed, a mask pattern 201 may be formed. The mask pattern 201 may be a photoresist pattern and may be formed by a coating process, an exposure process, and a development process each performed on the mask material layer 200. FIG. 9 is a flowchart illustrating in more detail an operation S120 of forming first and second preliminary recesses PRCS1 and PRCS2. A reticle SR including a scattering bar SB may be disposed on the upper surface at the second position, and thus, the mask material layer 200 on the upper surface at the second position may be exposed. For example, the scattering bar SB may be disposed on the upper surface at the second position, and the mask material layer 200 on the upper surface at the second position may be exposed. Also, an opened reticle SR may be disposed on the upper surface at the first position.

According to an example embodiment, the scattering bar SB may include a line and space pattern, an island pattern, or a combination thereof. Exposure energy passing through the scattering bar SB of the reticle SR may be reduced. Therefore, exposure energy reaching the mask material layer 200 on the upper surface at the second position corresponding to the scattering bar SB may be reduced. Referring to FIG. 9, the scattering bar SB of the reticle SR may be disposed on the upper surface at the second position in operation S121. In this case, the amount of exposure energy reaching the upper surface at the second position may be adjusted by adjusting a density of the scattering bar SB corresponding to the upper surface at the second position in operation S123. Therefore, a portion of the mask material layer 200 on the upper surface at each of the first and second positions may be removed in operation S125. Also, the degree of removal of the mask material layer 200 on the upper surface at the first position may be greater than the degree of removal of the mask material layer 200 on the upper surface at the second position. The mask material layer 200 on the upper surface at each of the first and second positions may be removed, and thus, the mask pattern 201 may be formed. Therefore, although described below, a depth of the first preliminary recess PRCS1 may be deeper than that of the second preliminary recess PRCS2.

Referring to FIGS. 7, 8C, and 9, a portion of the interlayer insulation layer 134 or the semiconductor substrate 101 at the first and second positions may be etched by using the mask pattern 201 as an etch mask in operation S125. Therefore, a portion of the first semiconductor substrate 101 at the first position may be exposed.

Referring to FIGS. 7, 8D, and 9, the first preliminary recess PRCS1 may be formed in the exposed semiconductor substrate 101 in operation S125. The first preliminary recess PRCS1 having a first depth H1 may be formed from an upper surface of the semiconductor substrate 101 at the first position. Subsequently, the second preliminary recess PRCS2 may be formed at the second position in operation S130. The first preliminary recess PRCS1 may be formed by etching the semiconductor substrate 101 at the first position, and then, the second preliminary recess PRCS2 may be formed by etching a portion of the interlayer insulation layer 134 at the second position.

According to an example embodiment, the second preliminary recess PRCS2 may be configured to include an opening portion where an opened width thereof is greater than that of an opening portion of the first preliminary recess PRCS1. The first preliminary recess PRCS1 or the second preliminary recess PRCS2 may have, for example, a circular shape, a polygonal shape, or an oval shape, which is planar. However, the inventive concepts are not limited thereto.

In some example embodiments, a deep reactive ion etching (DRIE) process may be performed for forming the first or second preliminary recess PRCS1 or PRCS2 at the first or second position.

Because the semiconductor substrate 101 at the first position and the interlayer insulation layer 134 at the second position have an etch selectivity, the first preliminary recess PRCS1 at the first position may not be etched or may be relatively slightly etched while the interlayer insulation layer 134 at the second position is being etched and removed.

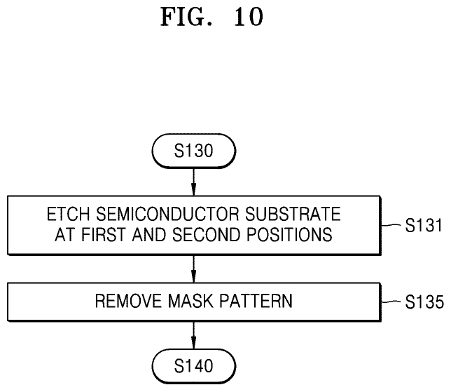

Referring to FIGS. 7, 8E, and 9, a first via structure via hole (referred to as a first via hole) 110H and a second via structure via hole (referred to as a second via hole) 120H, each having a second depth H2 which is greater than the first depth H1, may be formed by simultaneously etching the first and second preliminary recess PRCS1 and PRCS2. FIG. 10 is a flowchart illustrating in more detail an operation of forming the first via structure via hole 110H and the second via structure via hole 120H of FIG. 7.

The Deep Reactive Ion Etching (DRIE) process described above may be performed for forming the first via hole 110H and the second via hole 120H in operation S131. The first via hole 110H may have the first diameter D1, and the second via hole 120H may have the second diameter D2. The second diameter D2 may be greater than the first diameter D1. Because the second diameter D2 is greater than the first diameter D1, an etch speed in the second via hole 120H may be greater than an etch speed in the first via hole 110H. Because an etch speed of the semiconductor substrate 101 in the first via hole 110H is slower than an etch speed of the semiconductor substrate 101 in the second via hole 120H, a depth of the first via hole 110H may be the same as that of the second via hole 120H at a time at which etching ends.

Also, after the first preliminary recess PRCS1 is formed by using the DRIE process in the first via hole 110H, an undercut region UC may be formed in an interface between portions etched by another DRIE process (e.g., by further etching the semiconductor substrate 101 by using the DRIE process) for forming the other portion of the first via hole 110H. In other words, a vertical level of the undercut region UC of the first via hole 110H may correspond to a vertical level of a lower surface of the first preliminary recess PRCS1.

In FIGS. 8B to 8E, a side surface of each pattern is illustrated as an inclined surface instead of a vertical surface, but the inventive concept are not limited thereto. Based on a real manufacturing condition, a side surface of each pattern may be a vertical surface instead of an inclined surface.

Subsequently, a mask pattern 201 may be removed. The mask pattern 201 may be removed by a dissolving process using a solvent or an ashing process at an oxidation atmosphere in operation S135.

Referring to FIGS. 7 and 8F, a via insulation material layer 116m and a barrier material layer 114m may be sequentially formed on a sidewall and a lower surface of each of the first via hole 110H and the second via hole 120H and an exposed surface of the interlayer insulation layer 134.

The via insulation material layer 116m and the barrier material layer 114m may be formed by a PVD process, a CVD process, or an ALD process and a material available thereby has been described above with reference to FIG. 3, and thus, their detailed descriptions are omitted.

Also, a plug material layer 112m filling a space may be formed on the barrier material layer 114m. The plug material layer 112m may be formed by, for example, an electroplating process. For example, a metal seed layer (not shown) may be formed on a surface of the barrier material layer 114, and then a metal layer may be grown from the metal seed layer by an electroplating process, thereby forming the plug material layer 112m, filling the space on the barrier material layer 114m. The metal seed layer may include copper (Cu), a Cu alloy, Co, Ni, Ru, Co/Cu, or Ru/Cu. A PVD process may be used for forming the metal seed layer. A main material of the plug material layer 112m may use Cu or W. In some example embodiments, the plug material layer 112m may include Cu, CuSn, CuMg, CuNi, CuZn, CuPd, CuAu, CuW, W, or a W alloy, but is not limited thereto. The electroplating process may be performed at a temperature of about 10° C. to about 65° C. For example, the electroplating process may be performed at a room temperature. After the plug material layer 112m is formed, a resultant material where the plug material layer 112m is formed may be annealed at a temperature of about 150° C. to about 450° C.

Referring to FIGS. 7 and 8G, a first via structure 110 and a second via structure 120 may be formed by partially removing the plug material layer 112, the barrier material layer 114m, and the via insulation material layer 116m.

An operation of partially removing the plug material layer 112, the barrier material layer 114m, and the via insulation material layer 116m may be performed by, for example, a process such as a chemical mechanical polishing (CMP) process or an etch-back process.

Referring to FIGS. 7 and 8H, a plurality of metal wiring layers 142, a plurality of contact plugs 144, and a bonding pad 152, which are electrically connected to the first via plug 112, may be formed at a first position. Also, a plurality of metal wiring layers 142, a plurality of contact plugs 144, and a bonding pad 152, which are electrically connected to the second via plug 122, may be formed at a second position.

Subsequently, an upper insulation layer 150 partially exposing the bonding pads 152 may be formed, and an upper connection terminal 154 may be formed on the bonding pad 152.

Referring to FIGS. 7 and 8I, by removing a portion of the semiconductor substrate 101, an end portion of each of the first via structure 110 and the second via structure 120 may pass through a lower surface 101B of the semiconductor substrate 101 and may be exposed.

In some example embodiments, an operation of removing a portion of the semiconductor substrate 101 may be performed by, for example, a CMP process.

Also, a lower insulation layer 160 covering the lower surface 101B of the semiconductor substrate 101 may be formed. The lower insulation layer 160 may be formed to cover the first via structure 110 and the second via structure 120 each protruding from the lower surface 101B of the semiconductor substrate 101. In some example embodiments, the lower insulation layer 160 may be formed by a CVD process. In some example embodiments, the lower insulation layer 160 may include silicon oxide, silicon nitride, or a polymer.

Subsequently, referring to FIG. 3, a polishing process may be performed from an exposed surface of the lower insulation layer 160 until a planarized surface is obtained at the lower surface 101B of the semiconductor substrate 101, and lower surfaces of the first and second via structures 110 and 120 planarized at the lower surface 101B of the semiconductor substrate 101 may be exposed.

Subsequently, a conductive layer 172 and a connection terminal 174 connected to the first and second structures 110 and 120 may be formed.

The conductive layer 172 may configure an under bump metallization (UBM) layer and may include layers having various compositions on the basis of a material of the connection terminal 174. In some example embodiments, the conductive layer 172 may include Ti, Cu, Ni, Au, NiV, NiP, TiNi, TiW, TaN, Al, Pd, CrCu, or a combination thereof. For example, the conductive layer 172 may have a stack structure of Cr/Cu/Au, a stack structure of Cr/CrCu/Cu, a TiWCu compound, a stack structure of TiWCu/Cu, a stack structure of Ni/Cu, a stack structure of NiV/Cu, a stack structure of Ti/Ni, a stack structure of Ti/NiP, TiWNiV compound, a stack structure of Al/Ni/Au, a stack structure of Al/NiP/Au, a stack structure of Ti/TiNi/CuNi compound, a stack structure of Ti/Ni/Pd, a stack structure of Ni/Pd/Au, or a stack structure of NiP/Pd/Au.

The connection terminal 174 may include a conductive pad, a solder ball, a solder bump, or a redistribution conductive layer. The connection terminal 174 may be connected to lower surfaces of the first and second via structures 110 and 120 through the conductive layer 172. The connection terminal 174 may include Ni, Cu, Al, or combination thereof, but is not limited thereto.

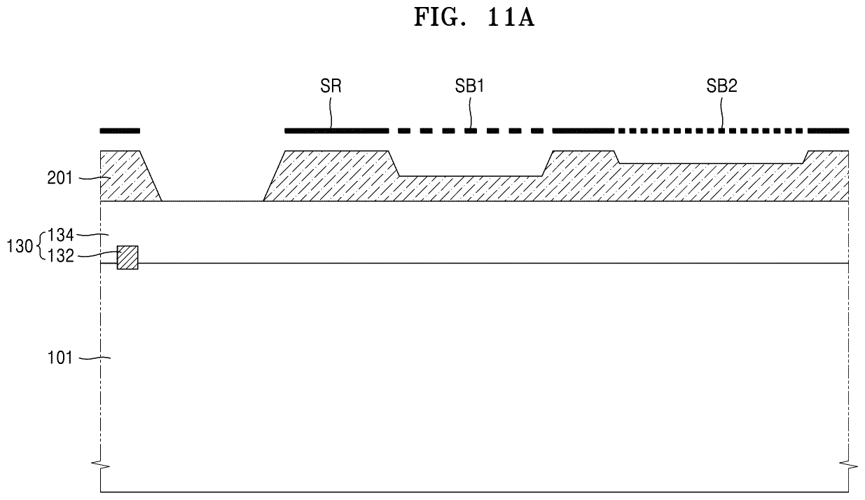

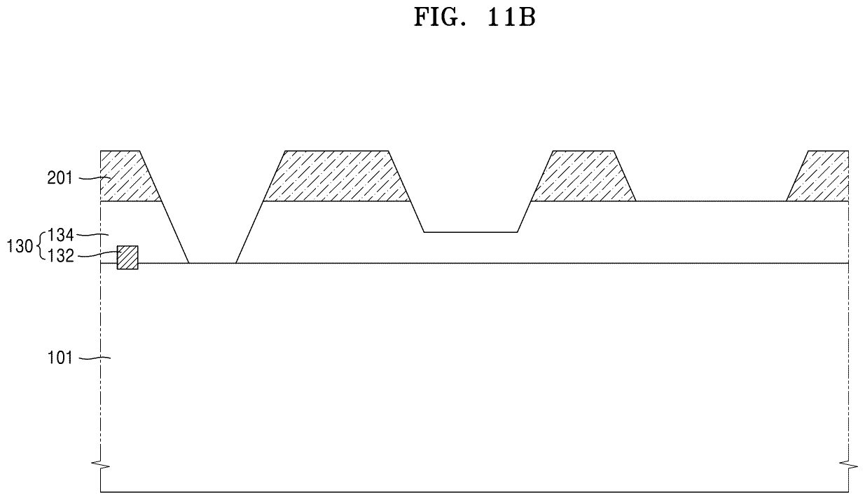

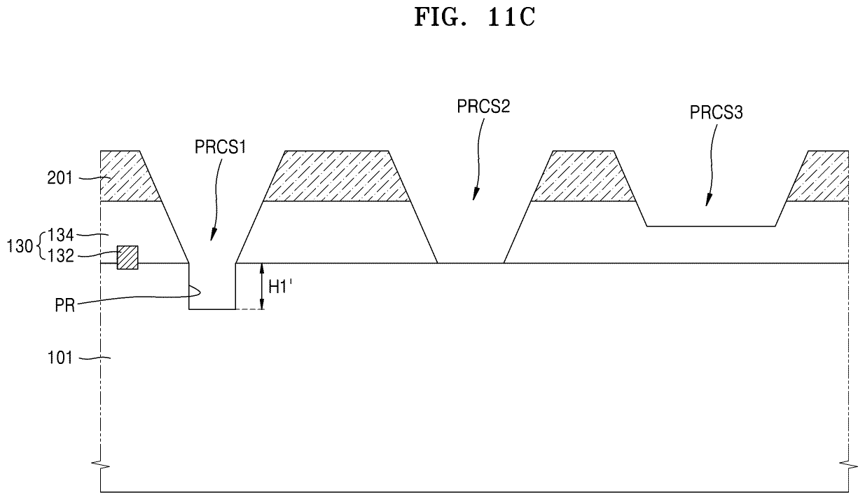

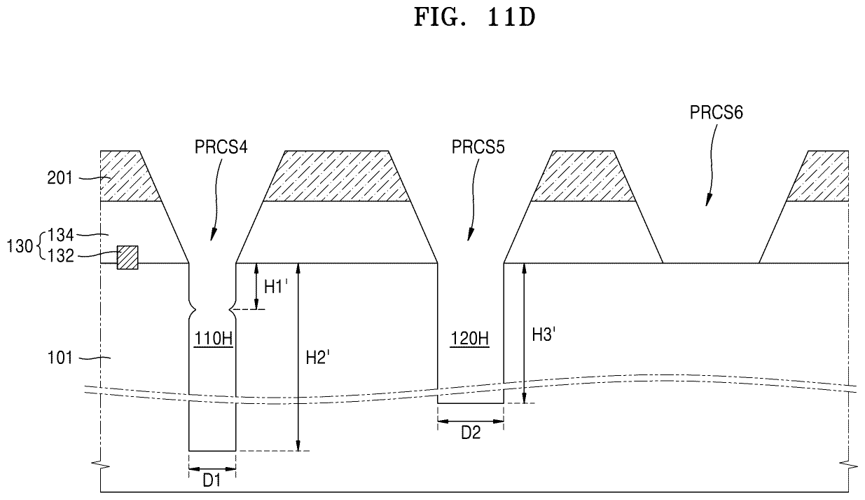

FIGS. 11A to 11D are side cross-sectional views illustrating a method of manufacturing a semiconductor device 100b, according to an example embodiment.

Referring to FIGS. 6 and 11A, an interlayer insulation layer 134 may be formed on a semiconductor substrate 101. In some example embodiments, a semiconductor device 132 may be formed on the semiconductor substrate 101 before forming the interlayer insulation layer 134. Subsequently, a mask material layer 200 may be coated and formed on the interlayer insulation layer 134.

Subsequently, first and second scattering bars SB1 and SB2 of a reticle SR may be disposed on an upper surface at each of a second position and a position (hereinafter referred to as a third position) for forming a third via structure 180. Also, an opened reticle SR may be disposed on an upper surface at the first position. A density of the first scattering bar SB1 disposed on the upper surface at the second position may be less than that of the second scattering bar SB2 disposed on the upper surface at the third position. Also, a removal depth of the mask material layer 200 on the upper surface at the third position may be less than that of the mask material layer 200 on the upper surface at the second position. Subsequently, an exposure process may be performed on the mask material layer 200 on the upper surface at each of the first to third positions.

Referring to FIGS. 6 and 11B, a portion of the interlayer insulation layer 134 or the semiconductor substrate 101 at each of the first to third positions may be etched. Therefore, a portion of the first semiconductor substrate 101 at the first position may be exposed.

Referring to FIGS. 6 and 11C, a first preliminary recess PRCS1 having a first depth H1′ from the semiconductor substrate 101 may be formed by etching the exposed semiconductor substrate 101. Therefore, a second preliminary recess PRCS2 may be formed in the interlayer insulation layer 134 at the second position while the first preliminary recess PRCS1 is being formed by etching the semiconductor substrate 101 at the first position, and a third preliminary recess PRCS3 may be formed in the interlayer insulation layer 134 at the third position. According to an example embodiment, the third preliminary recess PRCS3 may be configured to include an opening portion where an opened width thereof is greater than that of an opening portion of each of the first and second preliminary recesses PRCS1 and PRCS2. The first to third preliminary recesses PRCS1 to PRCS3 may have, for example, a circular shape, a polygonal shape, or an oval shape, which is planar. However, the inventive concepts are not limited thereto.

Referring to FIGS. 6 and 11D, a fourth preliminary recess PRCS4 may be formed by etching the semiconductor substrate 101 at the first position, and a fifth preliminary recess PRCS5 may be formed by etching the semiconductor substrate 101 at the second position. A second depth H2′ of the fourth preliminary recess PRCS4 from the semiconductor substrate 101 may be greater than a third depth H3′ of the fifth preliminary recess PRCS5 from the semiconductor substrate 101. Also, a portion of the semiconductor substrate 101 or the interlayer insulation layer 134 at the third position may be etched, and thus, a sixth preliminary recess PRCS6 may be formed. A depth of the sixth preliminary recess PRCS6 may be less than that of each of the fourth preliminary recess PRCS4 and the fifth preliminary recess PRCS5. Furthermore, an upper surface of the semiconductor substrate 101 at the third position may be exposed by removing a portion of the interlayer insulation layer 134 at the third position.

Subsequently, after the first to third via holes 110H to 130H are formed, the semiconductor device 100b of FIG. 6 may be manufactured by filling the first to third via holes 110H to 130H.

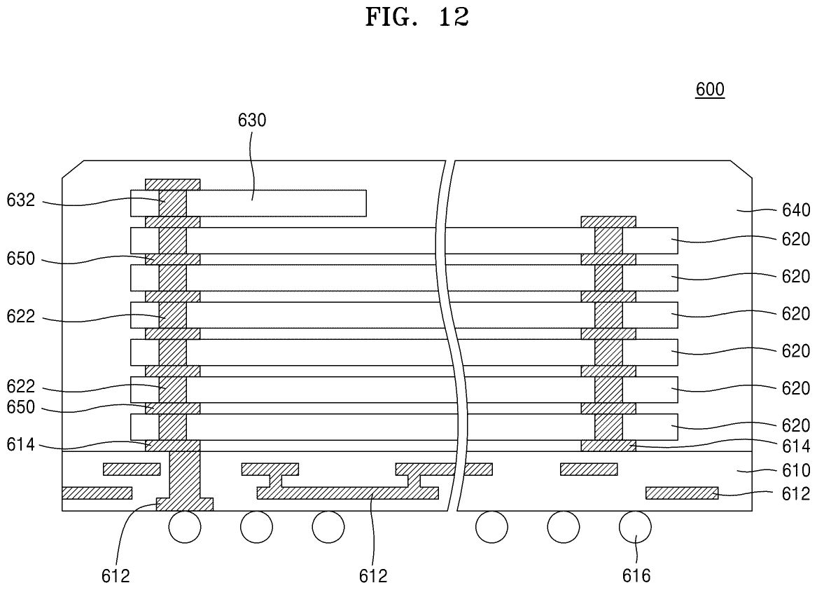

FIG. 12 is a cross-sectional view illustrating a main configuration of a semiconductor package 600 according to an example embodiment.

Referring to FIG. 12, the semiconductor package 600 may include a plurality of semiconductor chips 620 sequentially stacked on a package substrate 610. A control chip 630 may be connected to the plurality of semiconductor chips 620. A stack structure of the plurality of semiconductor chips 620 and the control chip 630 may be sealed by an encapsulant 640 such as a thermo-curable resin on the package substrate 610. In FIG. 12, a structure where six semiconductor chips 620 are vertically stacked is illustrated, but the number and stack direction of semiconductor chips 620 are not limited to the illustration. Depending on the case, the number of semiconductor chips 620 may be determined to be more or fewer than six. The plurality of semiconductor chips 620 may be arranged in a horizontal direction on the package substrate 610, or may be arranged in a connection structure where vertical-direction mounting and horizontal-direction mounting are combined. In some example embodiments, the control chip 630 may be omitted.

The package substrate 610 may include a flexible printed circuit board, a rigid printed circuit board, or a combination thereof. The package substrate 610 may include a substrate internal wiring 612 and a connection terminal 614. The connection terminal 614 may be formed on one surface of the package substrate 610. A solder ball 616 may be formed on the other surface of the package substrate 610. The connection terminal 614 may be electrically connected to the solder ball 616 through the substrate internal wiring 612. In some example embodiments, the solder ball 616 may be replaced with a conductive bump or a lead grid array (LGA).

The semiconductor package 600 may include via structure units 622 and 632. The via structure units 622 and 632 may be electrically connected to the connection terminal 614 of the package substrate 610 by the connection member 650 such as a bump. In some example embodiments, the via structure unit 632 may be omitted in the control chip 630.

At least one of the plurality of semiconductor chips 620 and the control chip 630 may include at least one of the semiconductor devices 100 described above with reference to FIGS. 1 to 11D.

Each of the plurality of semiconductor chips 620 may include system LSI, flash memory, dynamic random access memory (DRAM), static random access memory (SRAM), electrically erasable programmable read-only memory (EEPROM), phase change random access memory (PRAM), magnetic random access memory (MRAM), or resistance random access memory (RRAM). The control chip 630 may include, for example, logic circuits such as a serializer/deserializer (SER/DES) circuit.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a semiconductor substrate;
an interlayer insulation layer on the semiconductor substrate;
a first via structure passing through the semiconductor substrate and the interlayer insulation layer, the first via structure having a first diameter; and
a second via structure passing through the semiconductor substrate and the interlayer insulation layer, the second via structure having a second diameter, the second diameter being greater than the first diameter at a same vertical level,
wherein a sidewall of the first via structure comprises at least two first undercut regions horizontally protruding toward an inner portion of the first via structure,
a sidewall of the second via structure comprises at least one second undercut region horizontally protruding toward an inner portion of the second via structure, and
a vertical level of the second undercut region is between the two first undercut regions.

2. The semiconductor device of claim 1, wherein an outer sidewall of the first via structure is in contact with either the semiconductor substrate or the interlayer insulation layer at an area above the first undercut regions.

3. The semiconductor device of claim 1, wherein an outer sidewall of the second via structure is in contact with either the semiconductor substrate or the interlayer insulation layer at an area above the first undercut regions.

4. The semiconductor device of claim 1, wherein a number of first undercut regions is more than a number of the second undercut region.

5. The semiconductor device of claim 1, wherein the first via structure comprises:
a first via insulation layer extending along a sidewall of a first via hole to have a uniform thickness, the first via hole passing through the semiconductor substrate and the interlayer insulation layer,
a first barrier layer extending along a sidewall of the first via insulation layer to have a uniform thickness, and
a first via plug filling an inner space defined by the first barrier layer.

6. The semiconductor device of claim 5, wherein, in each of the first undercut regions, a sidewall of each of the first via insulation layer and the first barrier layer horizontally protrudes to an inner portion of the first via structure.

7. The semiconductor device of claim 1, wherein a height of the first via structure is same as a height of the second via structure.

8. A semiconductor device comprising:
a semiconductor substrate;
an interlayer insulation layer on the semiconductor substrate;
a signal via structure passing through the semiconductor substrate and the interlayer insulation layer; and
a power via structure passing through the semiconductor substrate and the interlayer insulation layer,
wherein a sidewall of the signal via structure comprises at least two first undercut regions horizontally protruding toward a horizontal center of the signal via structure,
a sidewall of the power via structure comprises at least one second undercut region horizontally protruding toward a horizontal center of the signal via structure,
a height of the signal via structure is same as a height of the power via structure,
the signal via structure has a first diameter and the power via structure has a second diameter, the second diameter being greater than the first diameter at a same vertical level,
a vertical level of the second undercut region is between the two first undercut regions, and
an outer sidewall of the power via structure is in contact with the semiconductor substrate or the interlayer insulation layer at an area above the second undercut region and is not in contact with any etch delay layer.

9. The semiconductor device of claim 8, wherein
the signal via structure comprises a signal via insulation layer and a signal barrier layer, and
a sidewall of each of the signal via insulation layer and the signal barrier layer horizontally protrudes to an inner portion of the signal via structure.

10. The semiconductor device of claim 8, wherein
the signal via structure comprises a scallop region on the signal via structure.

11. The semiconductor device of claim 10, wherein a horizontal width of the scallop region is less than a horizontal width of each of the first undercut regions.

12. The semiconductor device of claim 8, wherein each outer sidewall of the signal via structure and power via structure is not in contact with any etch delay layer.

13. The semiconductor device of claim 8, wherein a number of the first undercut regions exceeds a number of the second undercut region by one.

14. The semiconductor device of claim 8, wherein a range of a height of the signal via structure or the power via structure is 30 μm to 150 μm.

15. The semiconductor device of claim 8, wherein a range of a ratio of the second diameter to the first diameter is 110% to 200%.

16. A semiconductor device comprising:
a semiconductor substrate;
an interlayer insulation layer on the semiconductor substrate;
a first via structure passing through the semiconductor substrate and the interlayer insulation layer, the first via structure having a first diameter;
a second via structure passing through the semiconductor substrate and the interlayer insulation layer, the second via structure having a second diameter, the second diameter being greater than the first diameter at a same vertical level; and
a third via structure passing through the semiconductor substrate and the interlayer insulation layer, the third via structure having a third diameter, the third diameter being greater than the second diameter at a same vertical level,
wherein a sidewall of the first via structure comprises at least two first undercut regions horizontally protruding toward an inner portion of the first via structure,
a sidewall of the second via structure comprises at least one second undercut region horizontally protruding toward an inner portion of the second via structure, and
a vertical level of the second undercut region is between the two first undercut regions.

17. The semiconductor device of claim 16, wherein each outer sidewall of the first via structure, the second via structure and the third via structure is in contact with either the semiconductor substrate or the interlayer insulation layer at an area above the first undercut regions.

18. The semiconductor device of claim 16, wherein the third via structure does not include an undercut region.

19. The semiconductor device of claim 16, wherein a number of first undercut regions is more than a number of the at least one second undercut region.

20. The semiconductor device of claim 16, wherein the third diameter exceeds the second diameter by 1 μm to 5 μm.
